(19) United States
(12) Patent Application Publication
(10) Pub. No.: US 2021/0391392 A1
(43) Pub. Date: Dec. 16, 2021

(54) ORGANIC LIGHT-EMITTING DEVICE, DISPLAY PANEL, AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Fang Wang, Wuhan (CN)

(21) Appl. No.: 17/042,833

(22) PCT Filed: Jun. 19, 2020
(86) PCT No.: PCT/CN2020/097173

§ 371 Date: Sep. 28, 2020

(30) Foreign Application Priority Data
Jun. 11, 2020 (CN) 202010530191.8

(51) Int. Cl. H01L 27/32; H01L 51/50

(52) U.S. Cl. CPC H01L 27/3206; H01L 51/5036

(57) ABSTRACT

An organic light-emitting device, a display panel, and a display device are provided. The organic light-emitting device includes a mixed light-emitting layer. The mixed light-emitting layer includes a first blue light-emitting layer, a second blue light-emitting layer, and a yellow-green light-emitting layer. The second blue light-emitting layer is disposed parallel to the yellow-green light-emitting layer and on the first blue light-emitting layer.

### TECHNICAL FIELD

The present disclosure relates to a display device technology field, and more particularly to an organic light-emitting device, a display panel, and a display device.

### BACKGROUND

Active matrix flat display devices have advantages of a thin body, power saving, and no radiation and get wide applications. Organic light-emitting diode (OLED) display technology is flat display technology with development prospects and has characteristics of self-luminous, a simple structure, thinness, a fast response speed, a wide angle, low power consumption, and being capable of implementing flexible display. Organic light-emitting diode displays are praised as a “dream display”. Furthermore, investment of production devices of an organic light-emitting diode display is much less than that of a thin film transistor type liquid crystal display, and thus it has been favored by major display manufacturers and has become the main force of the third-generation display devices in the display technology field. At present, OLED is ready for mass production. With the further penetration of researches and continuous emergence of new technology, OLED display devices are bound to have a breakthrough development.

To implement a full-color OLED display, one way is implemented by a side-by-side structure by RGB sub pixels which emit light respectively. Another way is implemented by a cascade structure in which a white organic light-emitting diode (WOLED) and a color filter (CF) layer are stacked. In the WOLED, two or more light-emitting layers are connected by charge generation layers (CGL) to emit white light. RGB monochromatic lights are generated after the CF layer filters the white light. Since the light-emitting layers are stacked, the structure is called as a cascade structure. A high resolution of an OLED display can be implemented because accuracy mask technology is not required for the cascade structure of the WOLED and the CF layer. Accordingly, although medium-sized and small-sized OLED display panels adopt the side-by-side structure of RGB pixels, large-sized OLED display panels adopt the cascade structure of the WOLED and the CF layer.

In a large-sized display field, a white light OLED device adopts three light-emitting layers (a structure including blue light B+yellow light Y+blue light B as shown in FIG. 3) or four light-emitting layers (a structure including blue light B+yellow light Y+red light R+blue light B as shown in FIG. 4) to generate white light. In the above-mentioned conventional stacked layers of white light, the blue light adopts a conventional fluorescence material and has a low efficiency. Although the top blue light-emitting layer increases light extraction efficiency, difficulty of adjusting a microcavity is increased and power consumption of the device is increased.

### SUMMARY OF DISCLOSURE

An objective of the present disclosure is to provide an organic light-emitting device and a display device to solve the problems that power consumption of a white light organic light-emitting device is large and difficulty of adjusting a microcavity is large in the prior art.

To implement the above-mentioned objective, the present disclosure provides an organic light-emitting device, including a mixed light-emitting layer and configured to emit whit light;

the mixed light-emitting layer including: a first blue light-emitting layer; a second blue light-emitting layer disposed on the first blue light layer; and a yellow-green light-emitting layer disposed parallel to the second blue light-emitting layer and on the first blue light-emitting layer.

Further, the mixed light-emitting layer further includes: a red light-emitting layer disposed between the yellow-green light-emitting layer and the first blue light-emitting layer.

Further, the mixed light-emitting layer further includes: an exciton recombination area positioned between the first blue light-emitting layer and the second blue light-emitting layer.

Further, the exciton recombination area includes a host material.

Further, each of the first blue light-emitting layer and the second blue light-emitting layer includes a thermally activated delayed fluorescence material and a host material.

Further, a mass ratio of the thermally activated delayed fluorescence material is ranged from 10% to 60%, and a mass ratio of the host material is the rest percent.

Further, the first blue light-emitting layer and/or the second blue light-emitting layer further includes a blue fluorescent guest material.

Further, in the first blue light-emitting layer and/or the second blue light-emitting layer, a mass ratio of the thermally activated delayed fluorescence material is ranged from 10% to 50%, a mass ratio of the blue fluorescent guest material is ranged from 1% to 10%, and a mass ratio of the host material is the rest percent.

The present disclosure further provides a display panel. The display panel includes a plurality of the above-mentioned organic light-emitting devices arranged therein.

The present disclosure further provides a display device. The display device includes the above-mentioned display panel.

Advantageous effect is described as follows. In the organic light-emitting device of the present disclosure, the luminous efficiency of the blue light-emitting layers is increased by adding the thermally activated delayed fluorescence material. Furthermore, in a structure of the two stacked blue light-emitting layers formed by the first blue light-emitting layer and the second blue light-emitting layer and provided by the embodiment of the present disclosure, a difficulty of adjusting a microcavity can be decreased, the power consumption of the organic light-emitting device can be effectively decreased to decrease the power consumption of the display device. The exciton recombination area of the mixed light-emitting layer can slow down the aging of the device, and stability and use lifespan of the organic light-emitting layer can be increased.

### BRIEF DESCRIPTION OF DRAWINGS

To describe the technical solutions of the embodiments of the present disclosure more clearly, the following briefly introduces the accompanying drawings required for describing the embodiments. Apparently, the accompanying drawings in the following description show only some embodiments of the present disclosure, and those skilled in the art may still derive other drawings from these accompanying drawings without creative efforts.

FIG. 1 illustrates a layer structure diagram of a mixed light-emitting layer in accordance with Embodiment 1 of the present disclosure.

FIG. 2 illustrates a layer structure diagram of a mixed light-emitting layer in accordance with Embodiment 2 of the present disclosure.

FIG. 3 illustrates a layer structure diagram of three light-emitting layers in the prior art.

FIG. 4 illustrates a layer structure diagram of a four light-emitting layers in the prior art.

Elements in the drawings are numbered as follows:
mixed light-emitting layer 100;
first blue light-emitting layer 10; second blue light-emitting layer 20;
yellow-green light-emitting layer 30; red light-emitting layer 40;
exciton recombination area 50.

### DETAILED DESCRIPTION OF EMBODIMENTS

The following description of every embodiment with reference to the accompanying drawings is used to exemplify a specific embodiment, which may be carried out in the present disclosure. The embodiments completely introduce the present disclosure for those skilled in the art, which make technology content clear and understand. The present disclosure embodies through different types of the embodiments. The protection range of the present disclosure is not limited in the embodiments of the present disclosure.

In the drawings, the components having similar structures are denoted by the same numerals. The structures and the components have similar function can use similar numerals to express. Thicknesses and sizes of the components in the drawings are randomly shown. The present disclosure does not limit to the thicknesses and the sizes of the components in the drawings. In order to make the drawings clear, the thicknesses of some components in the drawings are properly increased.

Additionally, description will be given by the preferred embodiments along with the accompanied drawings. It can be used to implement a specific embodiment. Direction terms are mentioned in the present disclosure, for example, “upper”, “lower”, “front”, “back”, “left”, “right”, “inside”, “outside”, “side” and so on, only refer to the direction of accompanied drawings. Thus, it is better and clearer to describe and understand the present invention by using direction terms, rather than implying the devices or elements are referred to a specific direction, and a structure or an operation with a specific direction. Therefore, it cannot be understood the limit of the present disclosure. Furthermore, terms “first”, “second”, “third” and the like are only are only for the purpose of description and are not to be construed as indicating or implicit relative importance.

When a certain component is described to be “on” another component, the component may be located directly on the another component. Also, there may exist an intermediate component, the component is located on the intermediate component, and the intermediate component is located on the another component. When a certain component is described to be “mounted on” or “connected to” another component, it may be construed to be directly “mounted on” or directly “connected to”. Alternatively, the component is “mounted on” or “connected to” the another component via an intermediate component.

### Embodiment 1

An embodiment of the present disclosure provides an organic light-emitting device which is a white light OLED device, includes a mixed light-emitting layer 100 and configured to emit whit light.

As shown in FIG. 1, the mixed light-emitting layer 100 includes a first blue light-emitting layer 10, a second blue light-emitting layer 20, a yellow-green light-emitting layer 30, and an exciton recombination area 50.

The second blue light-emitting layer 20 is disposed on the first blue light layer 10. The yellow-green light-emitting layer 30 is disposed parallel to the second blue light-emitting layer 20 and on the first blue light-emitting layer 10. The first blue light-emitting layer 10, the second blue light-emitting layer 20, and the yellow-green light-emitting layer 30 simultaneously emit light according to a modulated ratio. The first blue light-emitting layer 10 and the second blue light-emitting layer 20 are configured to emit blue light, and the yellow-green light-emitting layer 30 is configured to emit yellow-green light. The blue light sources having corresponding ratios and the yellow-green source having a corresponding ratio are mixed to be the white light source which is used for providing a light source for a display device, thereby forming a display image which can be seen by a naked eye. In the mixed light-emitting layer 100 including a structure of the two stacked blue light-emitting layers and provided by the embodiment of the present disclosure, a structure of a top blue light-emitting layer in the prior art is removed. A difficulty of adjusting a microcavity can be decreased when light extraction efficiency of the blue light is guaranteed. Adjustment of white balance can be also guaranteed, thereby decreasing power consumption of the device.

Each of the first blue light-emitting layer 10 and the second blue light-emitting layer 20 includes a host material and a blue thermally activated delayed fluorescence (TADF) material. A mass ratio of the thermally activated delayed fluorescence material is ranged from 10% to 60%, and a mass ratio of the host material is the rest percent. The thermally activated delayed fluorescence material can increase internal quantum efficiency to 100% using singlet excitons and triplet excitons. Compared to a traditional blue fluorescence material in the prior art, the thermally activated delayed fluorescence material has a characteristic of delaying fluorescence, thereby increasing luminous efficiency effectively and decreasing the power consumption of the device.

The exciton recombination area 50 is disposed between the first blue light-emitting layer 10 and the second blue light-emitting layer 20. The exciton recombination area 50 includes a host material. The exciton recombination area 50 is an area in which excitons are formed by electrons and holes of the organic light-emitting device. In the prior art, cascaded charge generation layers (CGL) are usually used. However, the charge generation layers cannot disperse an exciton density of the mixed light-emitting layer 100. An accumulation of the excitons accelerates aging of the device. In the embodiment of the present disclosure, the charge generation layers are replaced by the host material of the mixed light-emitting layer 100. Diffusion of carriers forms the exciton recombination area 50. The exciton density of the mixed light-emitting layer 100 can be decreased. Triplet-triplet annihilation of excitons can be avoided. As such, roll-off of the efficiency of the organic light-emitting device can be decreased, aging speed of the device can be slowed down, and operating life and operating stability of the organic light-emitting device can be increased apparently.

Generally, the organic light-emitting device further includes an anode, a cathode, a hole injection hole, a hole transport layer, an electron injection hole, and an electron transport layer. The hole injection hole, the hole transport layer, and the anode are sequentially disposed at one side of the mixed light-emitting layer 100 and connected to the mixed light-emitting layer 100. The electron transport layer, the electron injection hole, and the cathode are disposed at the other side of the mixed light-emitting layer 100 and connected to the mixed light-emitting layer 100. When the organic light-emitting device is powered on and works, carriers are formed at the cathode due to a function of a voltage and thus a current is generated. The current flows form the cathode to the anode via the mixed light-emitting layer 100. Due to a function of an electric field, electrons are injected from the cathode to the electron injection layer, and holes are injected from the anode to the hole injection layer. The electron transport layer transmits the electrons in the electron injection layer into the mixed light-emitting layer 100, and the hole transport layer transmits the holes in the hole injection layer into the mixed light-emitting layer 100. The holes meet the electrons and combine with the electrons in the mixed light-emitting layer 100 to form the excitons to release energy, thereby facilitating the fluorescence material and a phosphorescent material to emit light to cause the organic light-emitting device to emit light.

An embodiment of the present disclosure further provides a display device. The display device includes a display panel including a row of the organic light-emitting devices disposed thereon and a color filter substrate. The color filter substrate is disposed on a light-emitting surface of the display panel. The color filter substrate filters and modulates the white light emitted by the display panel, thereby forming a color display image.

In the organic light-emitting device provided by the embodiment of the present disclosure, the luminous efficiency of the blue light-emitting layers is increased by adding the thermally activated delayed fluorescence material. Furthermore, in a structure of the two stacked blue light-emitting layers formed by the first blue light-emitting layer 10 and the second blue light-emitting layer 20 and provided by the embodiment of the present disclosure, a difficulty of adjusting a microcavity can be decreased, the power consumption of the organic light-emitting device can be effectively decreased to decrease the power consumption of the display device. Moreover, the exciton recombination area 50 can slow down the aging of the mixed light-emitting layer 100, and stability and use lifespan of the organic light-emitting layer can be increased.

### Embodiment 2

Another embodiment of the present disclosure provides an organic light-emitting device which is a white light OLED device, includes a mixed light-emitting layer 100 and configured to emit whit light.

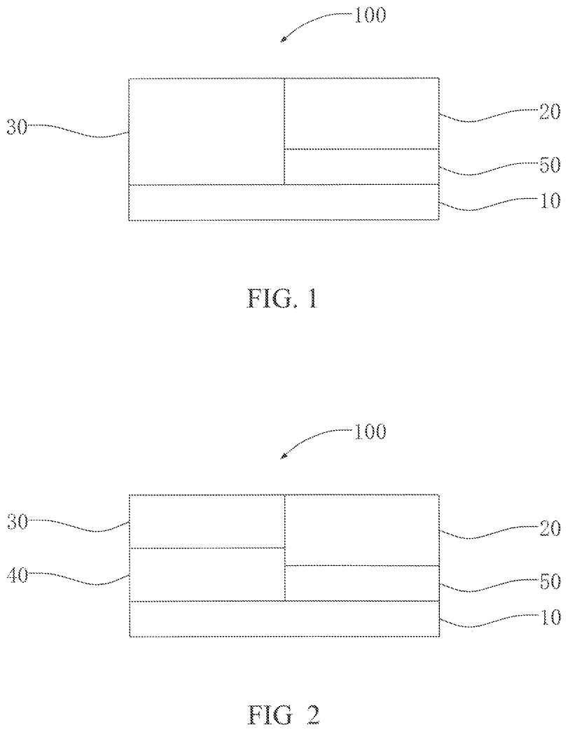

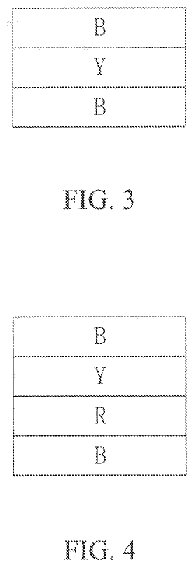

As shown in FIG. 2, the mixed light-emitting layer 100 includes a first blue light-emitting layer 10, a second blue light-emitting layer 20, a yellow-green light-emitting layer 30, a red light-emitting layer 40, and an exciton recombination area 50.

The second blue light-emitting layer 20 is disposed on the first blue light layer 10. The yellow-green light-emitting layer 30 is disposed parallel to the second blue light-emitting layer 20 and on the first blue light-emitting layer 10. The red light-emitting layer 40 is disposed between the yellow-green light-emitting layer 30 and the first blue light layer 10. The first blue light-emitting layer 10, the second blue light-emitting layer 20, the yellow-green light-emitting layer 30, and the red light-emitting layer 40 simultaneously emit light according to a modulated ratio. The first blue light-emitting layer 10 and the second blue light-emitting layer 20 are configured to emit blue light, the yellow-green light-emitting layer 30 is configured to emit yellow-green light, and the red light-emitting layer 40 is configured to emit red light. The blue light sources having corresponding ratios, the yellow-green source having a corresponding ratio, and the red light source having a corresponding ratio are mixed to be the white light source which is used for providing a light source for a display device, thereby forming a display image which can be seen by a naked eye. In the mixed light-emitting layer 100 including a structure of the two stacked blue light-emitting layers and provided by the embodiment of the present disclosure, a structure of a top blue light-emitting layer in the prior art is removed. A difficulty of adjusting a microcavity can be decreased when light extraction efficiency of the blue light is guaranteed. Adjustment of white balance can be also guaranteed, thereby decreasing power consumption of the device.

Each of the first blue light-emitting layer 10 and the second blue light-emitting layer 20 includes a host material, a blue fluorescent guest material, and a blue thermally activated delayed fluorescence (TADF) material. A mass ratio of the thermally activated delayed fluorescence material is ranged from 10% to 50%, a mass ratio of the blue fluorescent guest material is ranged from 1% to 10%, and a mass ratio of the host material is the rest percent. The thermally activated delayed fluorescence material can increase internal quantum efficiency to 100% using singlet excitons and triplet excitons. Compared to a traditional blue fluorescence guest material in the prior art, the thermally activated delayed fluorescence material has a characteristic of delaying fluorescence, thereby increasing luminous efficiency effectively and decreasing the power consumption of the device.

The exciton recombination area 50 is disposed between the first blue light-emitting layer 10 and the second blue light-emitting layer 20. The exciton recombination area 50 includes a host material. The exciton recombination area 50 is an area in which excitons are formed by electrons and holes of the organic light-emitting device. In the prior art, cascaded charge generation layers (CGL) are usually used. However, the charge generation layers cannot disperse an exciton density of the mixed light-emitting layer 100. An accumulation of the excitons accelerates aging of the device. In the embodiment of the present disclosure, the charge generation layers are replaced by the host material of the mixed light-emitting layer 100. Diffusion of carriers forms the exciton recombination area 50. The exciton density of the mixed light-emitting layer 100 can be decreased. Triplet-triplet annihilation of excitons can be avoided. As such, roll-off of the efficiency of the organic light-emitting device can be decreased, aging speed of the device can be slowed down, and operating life and operating stability of the organic light-emitting device can be increased apparently.

Generally, the organic light-emitting device further includes an anode, a cathode, a hole injection hole, a hole transport layer, an electron injection hole, and an electron transport layer. The hole injection hole, the hole transport layer, and the anode are sequentially disposed at one side of the mixed light-emitting layer 100 and connected to the mixed light-emitting layer 100. The electron transport layer, the electron injection hole, and the cathode are disposed at the other side of the mixed light-emitting layer 100 and connected to the mixed light-emitting layer 100. When the organic light-emitting device is powered on and works, carriers are formed at the cathode due to a function of a voltage and thus a current is generated. The current flows form the cathode to the anode via the mixed light-emitting layer 100. Due to a function of an electric field, electrons are injected from the cathode to the electron injection layer, and holes are injected from the anode to the hole injection layer. The electron transport layer transmits the electrons in the electron injection layer into the mixed light-emitting layer 100, and the hole transport layer transmits the holes in the hole injection layer into the mixed light-emitting layer 100. The holes meet the electrons and combine with the electrons in the mixed light-emitting layer 100 to form the excitons to release energy, thereby facilitating the fluorescence material and a phosphorescent material to emit light to cause the organic light-emitting device to emit light.

Another embodiment of the present disclosure further provides a display device. The display device includes a display panel including a row of the organic light-emitting devices disposed thereon and a color filter substrate. The color filter substrate is disposed on a light-emitting surface of the display panel. The color filter substrate filters and modulates the white light emitted by the display panel, thereby forming a color display image.

In the organic light-emitting device provided by the embodiment of the present disclosure, the luminous efficiency of the blue light-emitting layers is increased by adding the thermally activated delayed fluorescence material. Furthermore, in a structure of the two stacked blue light-emitting layers formed by the first blue light-emitting layer 10 and the second blue light-emitting layer 20 and provided by the embodiment of the present disclosure, a difficulty of adjusting a microcavity can be decreased, the power consumption of the organic light-emitting device can be effectively decreased to decrease the power consumption of the display device. Moreover, the exciton recombination area 50 can slow down the aging of the mixed light-emitting layer 100, and stability and use lifespan of the organic light-emitting layer can be increased.

Although the present disclosure is described with reference to specific embodiments, it can be understood that these embodiments are merely examples of the principles and applications of the present disclosure. Hence, it can be understood that numerous modifications can be made to the embodiments, and other arrangements can be made, as long as they do not go beyond the spirit and scope of the present disclosure as defined by the appended claims. It can be understood that different dependent claims and features described herein can be combined in a manner different from those described in the initial claims. It can also be understood that the technical features described in one embodiment can also be used in other embodiments.

What is claimed is:

1. An organic light-emitting device, comprising a mixed light-emitting layer and configured to emit whit light;
the mixed light-emitting layer comprising:
a first blue light-emitting layer;
a second blue light-emitting layer disposed on the first blue light layer; and
a yellow-green light-emitting layer disposed parallel to the second blue light-emitting layer and on the first blue light-emitting layer.

2. The organic light-emitting device of claim 1, wherein the mixed light-emitting layer further comprises:
a red light-emitting layer disposed between the yellow-green light-emitting layer and the first blue light-emitting layer.

3. The organic light-emitting device of claim 1, wherein the mixed light-emitting layer further comprises:
an exciton recombination area positioned between the first blue light-emitting layer and the second blue light-emitting layer.

4. The organic light-emitting device of claim 3, wherein the exciton recombination area comprises a host material.

5. The organic light-emitting device of claim 1, wherein each of the first blue light-emitting layer and the second blue light-emitting layer comprises a thermally activated delayed fluorescence material and a host material.

6. The organic light-emitting device of claim 5, wherein a mass ratio of the thermally activated delayed fluorescence material is ranged from 10% to 60%, and a mass ratio of the host material is the rest percent.

7. The organic light-emitting device of claim 5, wherein the first blue light-emitting layer and/or the second blue light-emitting layer further comprises a blue fluorescent guest material.

8. The organic light-emitting device of claim 7, wherein in the first blue light-emitting layer and/or the second blue light-emitting layer, a mass ratio of the thermally activated delayed fluorescence material is ranged from 10% to 50%, a mass ratio of the blue fluorescent guest material is ranged from 1% to 10%, and a mass ratio of the host material is the rest percent.

9. A display panel, comprising the organic light-emitting device of claim 1.

10. A display device, comprising the display panel of claim 9.
